(19) United States
(12) Patent Application Publication
(10) Pub. No.: US 2008/0286894 A1
(43) Pub. Date: Nov. 20, 2008

(54) GALLIUM NITRIDE BASED SEMICONDUCTOR LIGHT EMITTING DIODE AND PROCESS FOR PREPARING THE SAME

(75) Inventors: Seung Wan CHAE, Yongin (KR); Jun Sub KWAK, Yongin (KR); Hyoun Soo SHIN, Seoul (KR); Jun Ho SEO, Gunpo (KR)

Correspondence Address: LOWE HAUPTMAN HAM & BERNER, LLP, 1700 DIAGONAL ROAD, SUITE 300, ALEXANDRIA, VA, 22314, US

(73) Assignee: SAMSUNG ELECTRO-MECHANICS CO., LTD., Suwon (KR)

(21) Appl. No.: 12/166,113

(22) Filed: Jul. 1, 2008

Related U.S. Application Data
(62) Division of application No. 11/049,876, filed on Feb. 4, 2005.

(30) Foreign Application Priority Data
Aug. 10, 2004 (KR) 10-2004-62686

(51) Int. Cl. H01L 33/00

(52) U.S. Cl. 438/32; 257/E33.023; 257/E33.067

(57) ABSTRACT

A process for preparing a gallium nitride based semiconductor light emitting diode includes the step of: providing a substrate for growing a gallium nitride based semiconductor material; forming a lower clad layer on the substrate using a first conductive gallium nitride based semiconductor material; forming an active layer on the lower conductive clad layer using an undoped gallium nitride based semiconductor material; forming an upper clad layer on the active layer using a second conductive gallium nitride based semiconductor material; removing at least a portion of the upper clad layer and active layer at a predetermined region so as to expose the corresponding portion of the lower clad layer; and forming, on the upper surface of the upper clad layer, an ohmic contact forming layer made of In₂O₃ including at least one of Zn, Mg and Cu.

### RELATED APPLICATIONS

The present application is based on, and claims priority from, Korean Application Number 2004-62686, filed Aug. 10, 2004, the disclosure of which is hereby incorporated by reference herein in its entirety.

### BACKGROUND OF THE INVENTION

1. Field of the Invention

The present invention relates to a gallium nitride based semi-conductor light emitting diode, and more particularly to a gallium nitride based semiconductor light emitting diode having good luminance characteristics while being capable of operating at a low drive voltage by improving transparency of an electrode and at the same time, forming a good quality ohmic contact between a transparent electrode layer and upper clad layer, and a process for preparing the same.

2. Description of the Related Art

Recently, a great deal of attention has been directed to light emitting diodes using a gallium nitride (GaN) based semiconductor as a backlight source of a flat display device such as an LCD. Further, as a high luminance blue light LED using the gallium nitride (GaN) based semiconductor has also been introduced recently, full color display using red, yellow-green and blue light has become possible.

This gallium nitride based compound semiconductor light emitting diode is generally grown to be formed on an insulative substrate (a sapphire substrate is representatively used), thus electrodes cannot be mounted on the back side of the substrate like GaAs based compound semiconductor light emitting diodes. Therefore, the electrodes must be formed on a semiconductor layer having crystals grown thereon. FIG. 1 shows such a conventional structure of the gallium nitride based light emitting diode.

Referring to FIG. 1, the gallium nitride based light emitting diode comprises a sapphire growth substrate 11, and a lower clad layer 12 made of a first conductive semiconductor material, an active layer 13 and an upper clad layer 14 made of a second conductive semiconductor material formed sequentially thereon.

The lower clad layer 12 may be made of an n-type GaN layer 12a and an n-type AlGaN layer 12b. The active layer 13 may be made of an undoped InGaN layer having a Multi-Quantum Well structure. Further, the upper clad layer 14 may be composed of a p-type AlGaN layer 14a and a p-type GaN layer 14b.

Generally, the lower clad layer/active layer/upper clad layer 12, 13 and 14 made of the semiconductor crystals may be grown by using processes such as MOCVD (Metal Organic Chemical Vapor Deposition) and the like. A buffer layer such as AlN/GaN (not shown) may be formed between the sapphire substrate 11 and n-type GaN layer 12a of the lower clad layer 12 in order to improve lattice matching therebetween, prior to growing the n-type GaN layer 12a of the lower clad layer 12.

As described above, since the sapphire substrate 11 is electrically insulative, formation of the electrodes on the upper surface of the semiconductor layer may be achieved by etching the upper clad layer 14 and active layer 13, at a predetermined region, to expose a portion of the upper surface of the lower clad layer 12, and more specifically the n-type GaN layer 12a, corresponding to the predetermined region, and forming a first electrode 16 on the upper exposed surface portion of the n-type GaN layer 12a.

Meanwhile, since the upper clad layer 14 has a relatively high resistance, an additional layer capable of forming ohmic contact using a conventional electrode is required prior to forming a second electrode 17. For this purpose, U.S. Pat. No. 5,563,422 (Applicant: Nichia Chemical Industries, Ltd., issued on Oct. 8, 1996) proposes formation of a transparent electrode layer 15 made of Ni/Au to form an ohmic contact, prior to forming the second electrode 17 on the upper surface of the p-type GaN layer 14b.

The transparent electrode layer 15 may form an ohmic contact while increasing a current injection area to the P-type GaN layer 14b, thereby lowering the forward voltage (Vf). However, the transparent electrode layer 15 made of Ni/Au has low transparency of only about 60% to 70% even when it is heat treated, and such low transparency gives rise to lowering the overall light emission efficiency of the light emitting diode of interest when it is used in realizing a package by wire bonding.

To overcome this low transparency problem, there has been proposed formation of a layer of ITO (Indium Tin Oxide), known to have transparency of more than about 90%, in place of the Ni/Au layer, as the transparent electrode layer 15. However, since ITO is an n-type material, having a work function of 4.7 to 5.2 eV, which is lower than that of p-type GaN, direct vapor-deposition of ITO on the p-type GaN layer does not easily form an ohmic contact.

Thus, in order to form the ohmic contact by alleviating the difference between the work functions, a conventional attempt has been made to dope material having a low work function, such as Zn, on the p-GaN layer 14b, or dope high concentration of C thereon so as to reduce the work function of the p-GaN thus resulting in deposition of ITO. However, doped Zn or C has high mobility and thus prolonged use of the light emitting diode of interest may cause diffusion of doped Zn or C into the lower part of the p-type GaN layer resulting in problems such as deterioration of reliability of the light emitting diode.

As another method, there has been proposed a method involving growing an n+ GaN layer doped with a high concentration of Si on the n-type GaN layer, followed by vapor deposition of ITO, or involving alternately growing multiple pairs of Si-doped n+ InGaN/GaN layers, followed by vapor deposition of ITO. However, such a method may have a disadvantage of exhibiting unstable ohmic contact, depending on forming conditions.

Therefore, there remains a need for a gallium nitride based semiconductor light emitting diode having high transparency and at the same time, capable of forming good ohmic contact between the p-GaN layer and electrode, in order to form the electrode of the GaN light emitting diode; and a process for preparing the same, in the related art.

### SUMMARY OF THE INVENTION

Therefore, the present invention has been made in view of the above problems, and it is an object of the present invention to provide a gallium nitride based semiconductor light emitting diode having high transparency and at the same time, improved contact resistance between the p-type GaN layer and electrode.

It is another object of the present invention to provide a process for preparing a gallium nitride based semiconductor light emitting diode having high transparency and at the same time, improved contact resistance between the p-type GaN layer and electrode.

In accordance with the present invention, the above and other objects can be accomplished by the provision of a gallium nitride based semiconductor light emitting diode comprising:

a substrate for growing a gallium nitride based semiconductor material;

a lower clad layer formed on the substrate and made of a first conductive gallium nitride based semiconductor material;

an active layer formed on the lower clad layer at a predetermined region thereof and made of an undoped gallium nitride based semiconductor material;

an upper clad layer formed on the active layer and made of a second conductive gallium nitride based semiconductor material;

an ohmic contact forming layer formed on the upper clad layer and made of In₂O₃ including at least one of Zn, Mg and Cu;

a transparent electrode layer formed on the upper part of the ohmic contact forming layer; and

first and second electrodes formed on the lower and upper clad layers, respectively.

The ohmic contact forming layer may form an ohmic contact between the upper clad layer and a second electrode while improving transparency characteristics.

Further, in the gallium nitride based semiconductor light emitting diode in accordance with the present invention, the upper clad layer may be comprised of a p-type GaN layer and a p-type AlGaN layer sequentially formed on the upper part of the active layer. The transparent electrode layer may be made of at least one of ITO (Indium Tin Oxide), ZnO and MgO.

In addition, the gallium nitride based semiconductor light emitting diode in accordance with the present invention may further comprise one or more metal layers formed between the ohmic contact forming layer and the transparent electrode layer, and made of one metal selected from the group consisting of Ag, Pt, Au, Co and Ir and thereby the ohmic contact may be formed more easily.

Preferably, the ohmic contact forming layer has a thickness of less than about 100 Å. The transparent electrode layer may have a thickness of less than several thousands of Å.

Further, the gallium nitride based semiconductor light emitting diode in accordance with the present invention may further comprise a reflective layer formed on the lower surface of the substrate and reflecting light emitted toward the substrate upward, thus improving luminance of the diode. The reflective layer may include a plurality of high refractivity optical thin films and a plurality of low refractivity optical thin films alternatively laminated thereon. In this connection, the high/low refractivity optical thin films as set forth in claim 8 of the present invention may be made of an oxide or nitride film, this film being a compound of one of Si, Zr, Ta, Ti and Al, and O or N, and the thickness of a single optical thin film being between about 300 and 800 Å and the total thickness of the reflective layer determined depending on the refractive index of the optical thin film.

In accordance with another aspect of the present invention, there is provided a process for preparing a gallium nitride based semiconductor light emitting diode comprising:

providing a substrate for growing a gallium nitride based semiconductor material;

forming a lower clad layer on the substrate using a first conductive gallium nitride based semiconductor material;

forming an active layer on the lower conductive clad layer using an undoped gallium nitride based semiconductor material;

forming an upper clad layer on the active layer using a second conductive gallium nitride based semiconductor material;

removing at least a portion of the upper clad layer and active layer at a predetermined region so as to expose a portion of the lower clad layer corresponding to the predetermined region; and

forming, on the upper surface of the upper clad layer, an ohmic contact forming layer made of In₂O₃ including at least one of Zn, Mg and Cu.

The step of forming the ohmic contact forming layer may include forming an alloy layer in a thickness of less than 100 Å on the upper clad layer, or may include vapor-depositing In₂O₃ including one of Mg, Zn and Cu in a predetermined thickness on the upper clad layer followed by heat treatment. Preferably, heat treatment is performed at a temperature of more than about 200° C. for more than 10 sec.

In addition, the process for preparing a gallium nitride based semiconductor light emitting diode of the present invention may further comprise forming a transparent electrode layer on the upper part of the ohmic contact forming layer. At this time, the ohmic contact forming layer may lower the work function of the upper clad layer and then form ohmic contact between the transparent electrode layer and the upper clad layer.

Also, the process for preparing a gallium nitride based semiconductor light emitting diode of the present invention may further comprise forming, on the upper part of the ohmic contact forming layer, one or more metal layers made of one metal selected from the group consisting of Ag, Pt, Au, Co and Ir, and further forming, on the lower surface of the substrate, a reflective layer reflecting light emitted toward the substrate upward. The reflective layer may include a plurality of high refractivity optical thin films and a plurality of low refractivity optical thin films alternatively laminated thereon. In this connection, as the optical thin films, high and low refractivity optical thin films may be established from an oxide or nitride film, this film being a compound of one of Si, Zr, Ta, Ti and Al, and O or N.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a perspective view showing a representative example of a conventional gallium nitride based semiconductor light emitting diode;

FIG. 2 is a perspective view showing a gallium nitride based semiconductor light emitting diode in accordance with the present invention;

FIGS. 3a and 3b are, respectively, perspective views showing applied embodiments of a gallium nitride based semiconductor light emitting diode in accordance with the present invention;

FIG. 4 is a flow chart schematically illustrating a process for preparing a gallium nitride based semiconductor light emitting diode in accordance with the present invention;

FIGS. 5a and 5b are a graph comparing transparency with respect to thickness of an ohmic contact forming layer and a temperature of heat treatment, in a gallium nitride based semiconductor light emitting diode in accordance with the present invention;

FIGS. 6a and 6b are, respectively, a graph comparing transparency and injection current of a gallium nitride based semiconductor light emitting diode, using MIO of the present invention;

FIGS. 7a through 7c show comparison results of injection current and transparency between a gallium nitride based semiconductor light emitting diode in accordance with the present invention and a conventional gallium nitride based semiconductor light emitting diode; and

FIGS. 8a and 8b are, respectively, a graph showing progress of PO and VF characteristics of the light emitting diode with respect to whether a reflective layer is present or not, in a gallium nitride based semiconductor light emitting diode in accordance with the present invention.

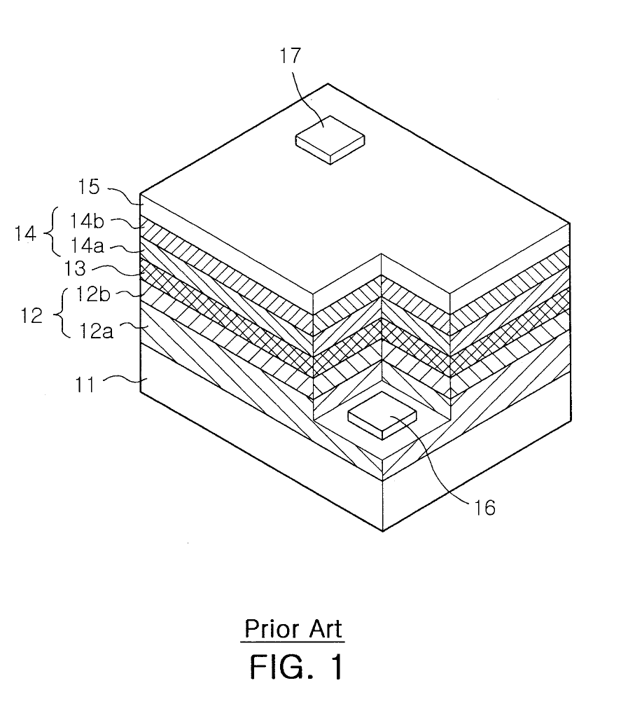

### DESCRIPTION OF THE PREFERRED EMBODIMENTS

A gallium nitride based semiconductor light emitting diode in accordance with the present invention will now be described in detail with reference to the annexed drawings.

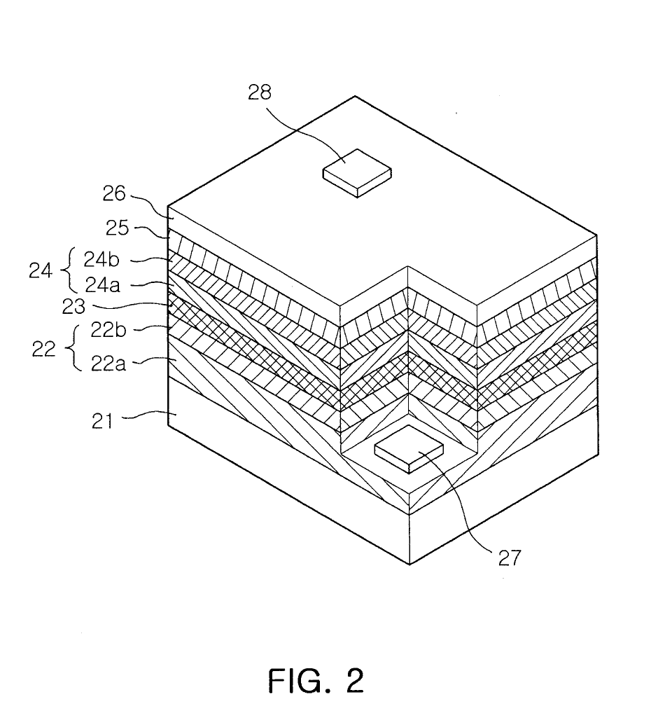

FIG. 2 is a cross-sectional side view showing a structure of a gallium nitride based semiconductor light-emitting diode in accordance with one embodiment of the present invention.

As shown in FIG. 2, the gallium nitride based semiconductor light-emitting diode in accordance with the present invention comprises a sapphire substrate 21 for growing the gallium nitride based semiconductor material, and a lower clad layer 22 made of a first conductive semiconductor material, an active layer 23, an upper clad layer 24 made of a second conductive semiconductor material, an ohmic contact forming layer 25, a transparent electrode layer 26 and first and second electrodes 27 and 28, these layers being formed sequentially on the sapphire substrate 21.

The lower clad layer 22 may be made of an n-type GaN layer 22a and an n-type AlGaN layer 22b. The active layer 23 may be made of an undoped InGaN layer having a multi-quantum well structure. Further, the upper clad layer 24 may be composed of a p-type AlGaN layer 24a and a p-type GaN layer 24b. The above-mentioned semiconductor crystalline layer 22, 23 and 24 may be grown using various processes such as MOCVD (Metal Organic Chemical Vapor Deposition), as described above. At this time, in order to improve lattice matching between the n-type GaN layer 22a and sapphire substrate 21, a buffer layer such as AlN/GaN (not shown) may be additionally formed on the upper part of the sapphire substrate 21.

A portion of the upper surface of the lower clad layer 22 is exposed at a predetermined region from which a portion of the upper clad layer 24 and active layer 23 corresponding to the predetermined region is removed. The first electrode 27 is disposed on the upper exposed surface portion of the lower clad layer 22, in particular the n-type GaN layer 22a.

In addition, the transparent electrode layer 26 and ohmic contact forming layer 25 are formed between the second electrode 28 and upper clad layer 24.

The transparent electrode layer 26 and ohmic contact forming layer 25 serve to form ohmic contact between the p-type GaN layer 24b, which has relatively high resistance and large work function (about 7.5 eV) as compared to the n-type GaN layer 22a, and the second electrode 28, and increase a current injection amount while simultaneously maintaining transparency above a predetermined level, thus improving luminance characteristics of the light emitting diode.

More specifically, the transparent electrode layer 26 may be formed of ITO, ZnO or MgO. Among those materials, ITO has good transparency, but is an n-type material, thus having a lower work function than the p-type GaN, and thereby it is difficult to form ohmic contact with the upper clad layer 24. Therefore, in the light emitting diode in accordance with the present invention, forming the ohmic contact forming layer 25 therebetween effects ohmic contact between the upper clad layer 24 and transparent electrode layer 26. The ohmic contact forming layer 25 may be formed of In₂O₃ including one of Mg, Zn and Cu (hereinafter, referred to as MIO, ZIO and CIO, respectively). The ohmic contact forming layer 25 may reduce the work function of the upper clad layer 24 and thus inhibit increase of forward voltage (VF) due to the difference between the work functions, thereby forming ohmic contact leading to improved contact resistance.

That is, impurities such as Mg, Cu and Zn are doped in a very low concentration on the surface of the p-type GaN layer 24b. As a result, ohmic resistance of the p-type GaN layer 24b is further increased. In addition, the light emitting diode of the present invention may provide further improvement of transparency by vapor depositing the ohmic contact forming layer 25 and transparent electrode 26 in a thickness of several hundreds of Å and several thousands of Å, respectively, on the upper surface of the p-type GaN layer 24b followed by heat treatment. The ohmic contact forming layer 25 preferably has a thickness of less than 100 Å.

Further, the gallium nitride based semiconductor light-emitting diode in accordance with the present invention may further comprise a metal layer (not shown) between the ohmic contact forming layer 25 and transparent electrode layer 26. The metal layer, when the semiconductor light emitting diode is packaged by wire bonding, is formed by forming one or more metal layer made of one metal selected from the group consisting of Ag, Pt, Au, Co and Ir, on the ohmic contact forming layer 25. Addition of such a metal layer may increase current diffusion and transparency in the blue and green light region.

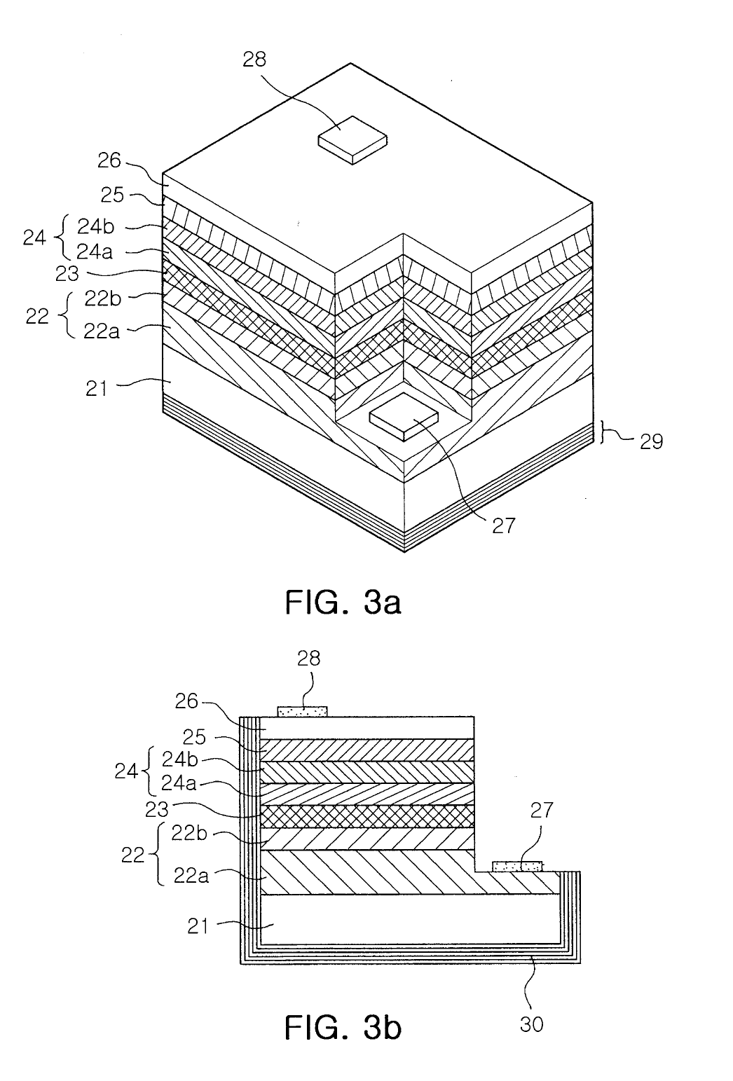

FIGS. 3a and 3b are cross-sectional views showing the structure of the gallium nitride based semiconductor light-emitting diode in accordance with another embodiment of the present invention. The gallium nitride based semiconductor light-emitting diode in accordance with the present invention comprises a sapphire substrate 21 for growing a gallium nitride based semiconductor material, and a lower clad layer 22 made of a first conductive semiconductor material, an active layer 23, an upper clad layer 24 made of a second conductive semiconductor material, an ohmic contact forming layer 25, a transparent electrode layer 26 and first and second electrodes 27 and 28, these layers being formed sequentially on the sapphire substrate 21.

In addition, the gallium nitride based semiconductor light-emitting diode shown in FIG. 3a may further comprise a reflective layer 29 formed on the lower surface of the substrate 21 and reflecting light transmitted through the substrate 21 upward.

Alternatively, the gallium nitride based semiconductor light-emitting diode shown in FIG. 3b may further comprise a reflective layer 30 formed on the remaining lower and side surfaces of the light emitting diode, except the direction of light emission of the diode (upper surfaces of the light emitting diode in the above embodiment), and reflecting light entering the corresponding direction upward.

The reflective layer 29, 30 formed on the lower surface, or lower and side surfaces of the light emitting diode reflects the light emitted to whole directions from the active layer 23 upward and thereby luminance characteristics of the packaged light-emitting diode can be further improved.

The reflective layer 29, 30 may be formed using a mirror coating film composed of one pair of high and low refractivity optical thin films, this mirror coating film being made of a plurality of alternatively laminated high and low refractivity optical thin films. The reflective layer 29, 30 of the mirror coating structure has a light reflection property and reflectivity thereof increases with increase of difference of refractivity. At this time, one pair of optical thin films may be formed of a metal, oxide or nitride film made of a compound of one of Si, Zr, Ta, Ti and Al, and O or N. Such an oxide or nitride film is vapor deposited in a thickness of 300 to 800 Å for a single film. The thickness of the reflective layer 29 is determined depending on refractivity of the oxide or nitride film.

Where the mirror coating structure is formed using the pair of SiO₂, having a refractivity of 1.47, and Si₃N₄, having a refractivity of more than 2, for example, the reflectivity of the reflective layer 29, 30 is more than 98%.

Further, the reflective layer 29, 30 may also be formed on the side of the light emitting diode in addition to the lower surface of the substrate 21.

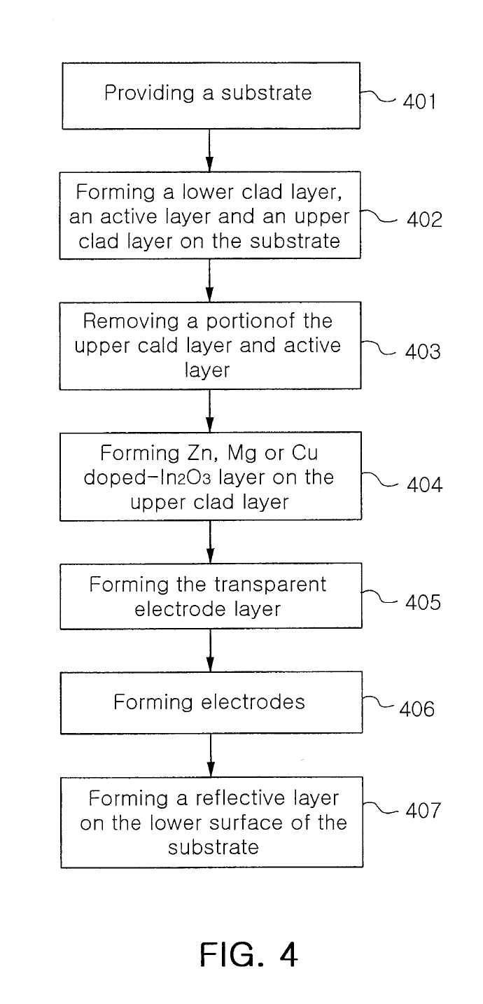

FIG. 4 is a flow chart sequentially illustrating a process for preparing a gallium nitride based semiconductor light emitting diode in accordance with the present invention.

Referring to FIG. 4, first, the substrate 21 for growing a gallium nitride based semiconductor material is provided (step 401), and then the lower clad layer 22 made of the first conductive semiconductor material, the active layer 23 and the upper clad layer 24 made of a second semiconductor material are sequentially formed on the upper surface of the substrate (step 402).

As the substrate for growing the semiconductor material, a sapphire substrate may be used. The lower clad layer 22 and upper clad layer 24 may be made by successive formation of a AlGaN layer and GaN layer, respectively, as in the previous embodiment and this may be attained by MOCVD.

Next, a portion of the upper clad layer 24 and active layer 23 are removed so as to expose the corresponding region of the lower clad layer 22 (step 403). The exposed region of the lower clad layer 21 thus provided enables the lower clad layer 21 to contact the electrode. The shape of the structure in accordance with this removing process may be varied depending on the position of the electrode to be formed, and the shape and size of the electrode. For example, the structure of the light emitting diode may be embodied in such a manner that the upper clad layer 24 and active layer 23 in the region facing one corner of the light emitting diode are removed. In addition, when the length of the electrode further extends in order to disperse current density, the region to be removed may also be extended corresponding to the electrode of interest.

Next, in the preparation process of the present invention, the ohmic contact forming layer 25 and transparent electrode 26 are sequentially formed on the upper clad layer 21 (step 404). The ohmic contact forming layer 25 may be formed by vapor depositing In₂O₃ including one of Mg, Zn and Cu in a predetermined thickness, in order to form an ohmic contact. At this time, the ohmic contact forming layer 25 has a thickness of less than several hundreds of Å, and preferably, less than 100 Å. Also, formation of the transparent electrode layer 26 is carried out by vapor depositing ITO, MgO or ZnO in a thickness of several thousands of Å on the ohmic contact forming layer 25. After both the ohmic contact forming layer 25 and transparent electrode layer 26 are vapor deposited, heat treatment may be performed at a predetermined temperature in order to improve transparency. Preferably, the heat treatment may be performed at above 200° C. for more than 10 sec.

Therefore, when formation of the transparent electrode layer 26 is also completed, the first and second electrodes 27 and 28 are simultaneously formed on upper surfaces of the lower clad layer 22 and transparent electrode layer 26, respectively (step 406).

In this connection, the process may further comprise laminating one or more metal layers made of a metal selected from the group consisting of Ag, Pt, Au, Co or Ir, on the ohmic contact forming layer 25, prior to forming the transparent electrode layer 26. The metal layer thus formed may increase current diffusion and transparency to light in the blue and green region.

Further, the process for preparing a light emitting diode in accordance with the present invention may further comprise forming the reflective layer 29 on the lower surface of the substrate 21 (step 407), when the wire bonding method packages the light emitting diode of interest.

The reflective layer 29 may be formed by alternatively laminating the high and low refractivity optical thin films.

The optical thin films may be implemented with the oxide or nitride film, this film being a compound of one of Si, Zr, Ta, Ti and Al, and O or N.

The reflective layer 29 thus formed reflects light transmitted and scattered through the substrate 21 upward, and thus luminance characteristics of the wire bonding type light emitting diode may be further improved.

Now, characteristics of the gallium nitride based semiconductor light emitting diode in accordance with the present invention will be described through a variety of experiment results.

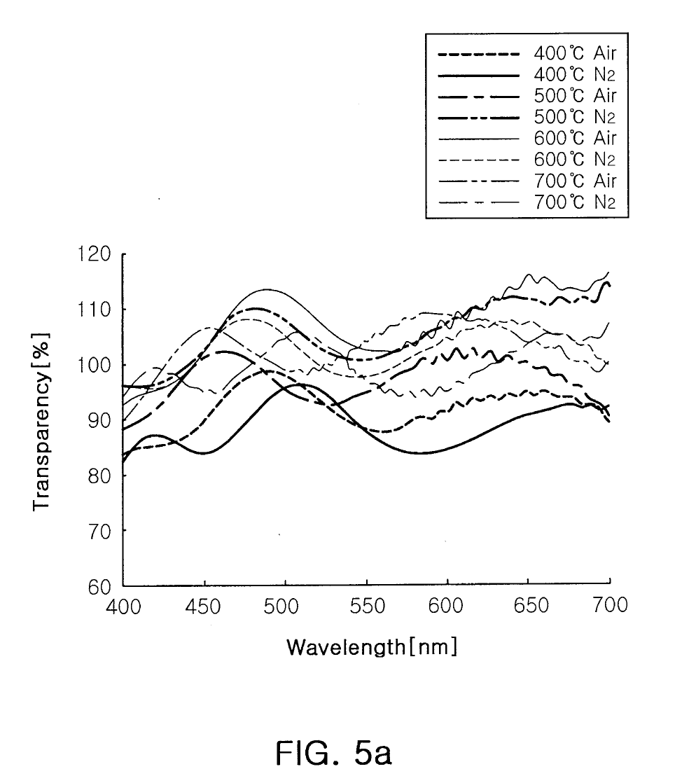

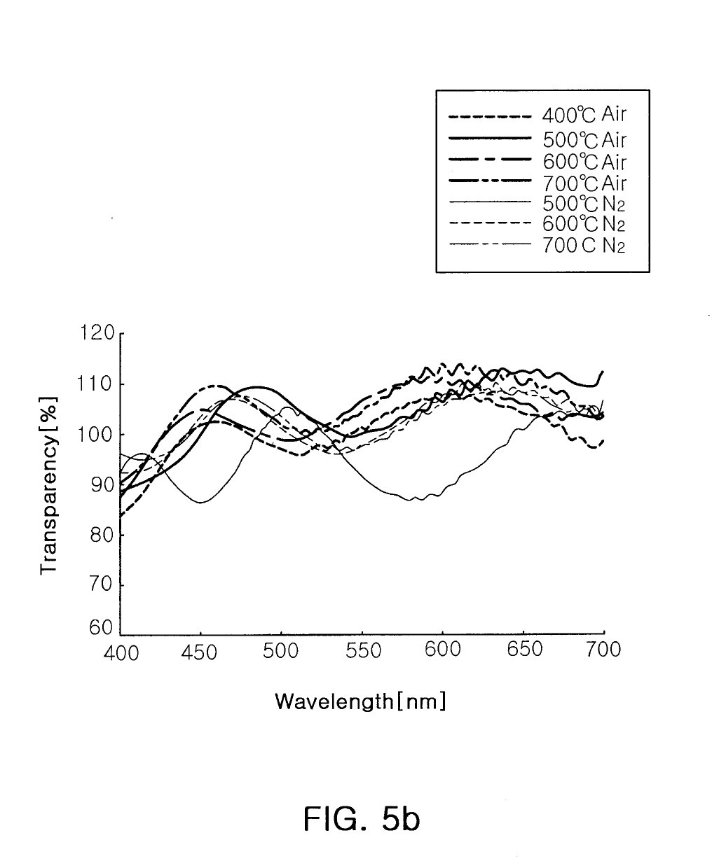

FIGS. 5a and 5b are graphs comparing transparency characteristics with respect to thickness of the ohmic contact forming layer 25 and temperature of heat treatment, in a gallium nitride based semiconductor light emitting diode in accordance with the present invention. The graph of FIG. 5a shows the comparison of transparency after heat treatment in air and N₂ atmosphere, at a temperature of 400 to 700° C., respectively, following formation of the ohmic contact forming layer made of CIO (In₂O₃ including Cu) in the thickness of 30 Å. FIG. 5b shows the comparison of transparency after heat treatment in air and N₂ atmosphere, at a temperature of 400 to 700° C., respectively, following formation of the ohmic contact forming layer made of CIO (In₂O₃ including Cu) in the thickness of 100 Å. As can be seen from the graphs of FIGS. 5a and 5b, the gallium nitride based semiconductor light emitting diode in accordance with the present invention has good transparency of more than 80% under any conditions and shows greater transparency with decreased thickness.

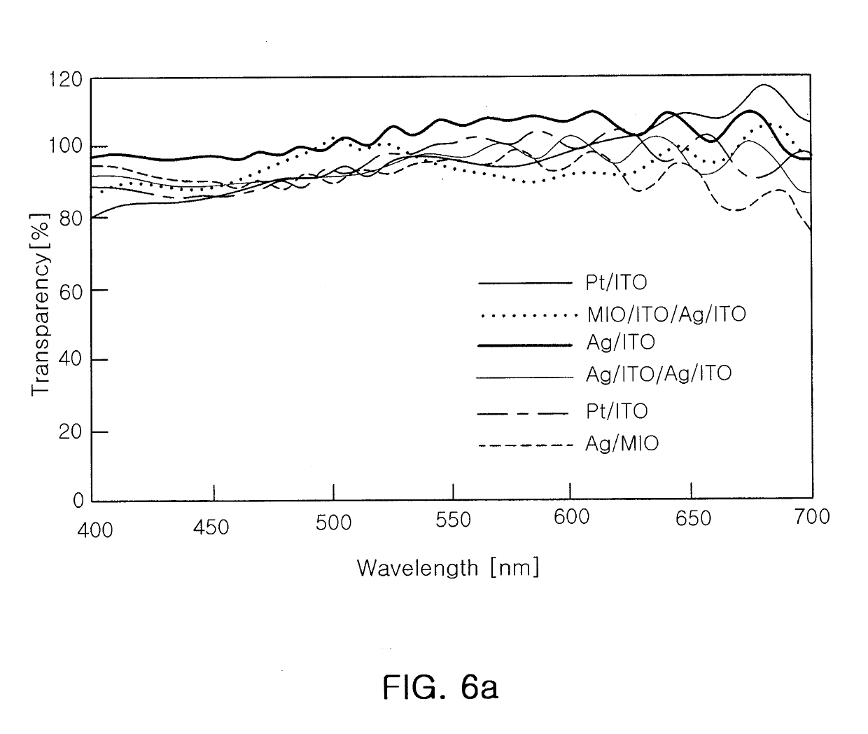

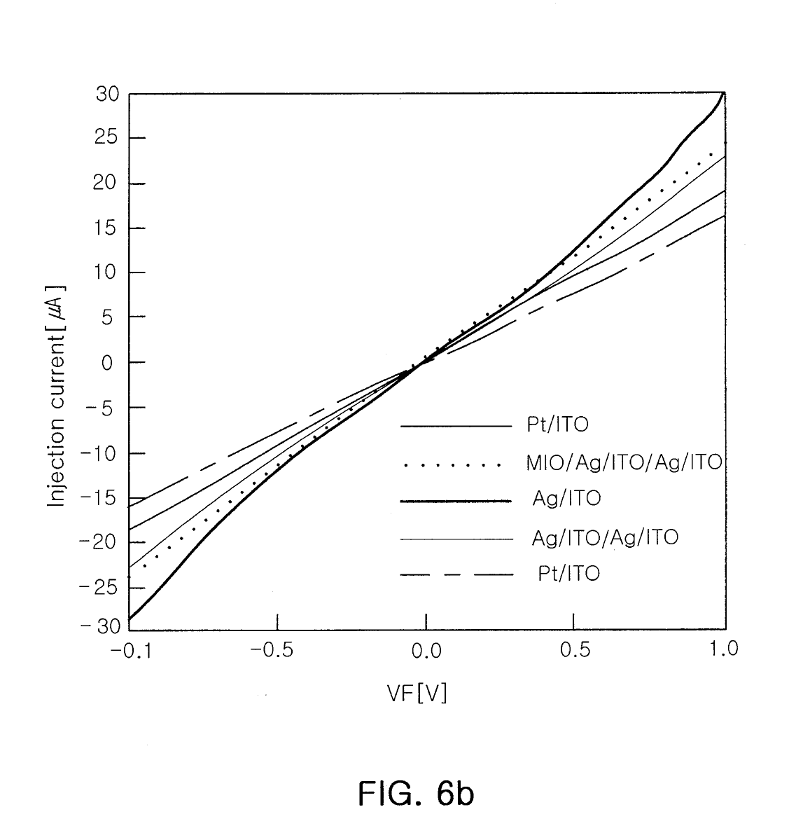

FIGS. 6a and 6b are graphs showing results of other experiments on a gallium nitride based semiconductor light emitting diode in accordance with the present invention. In this experiment, the ohmic contact forming layer 25 is formed in a thickness of 30 Å using MIO (In₂O₃ including Mg) and then characteristics thereof are compared with the light emitting diode formed with conventional Pt/ITO and Ag/ITO. First, FIG. 6a shows comparison of transparency between the inventive light emitting diode and conventional light emitting diode, and as can be seen, formation of the ohmic contact forming layer of MIO may enhance transparency of blue and green light and thus minimize loss of light. FIG. 6b shows comparison of ohmic formation between the inventive gallium nitride based light emitting diode formed of the ohmic contact forming layer of MIO and the conventional light emitting diode and as can be seen, the gallium nitride based semiconductor light emitting diode of the present invention has an ohmic formation equivalent to the conventional light emitting diode.

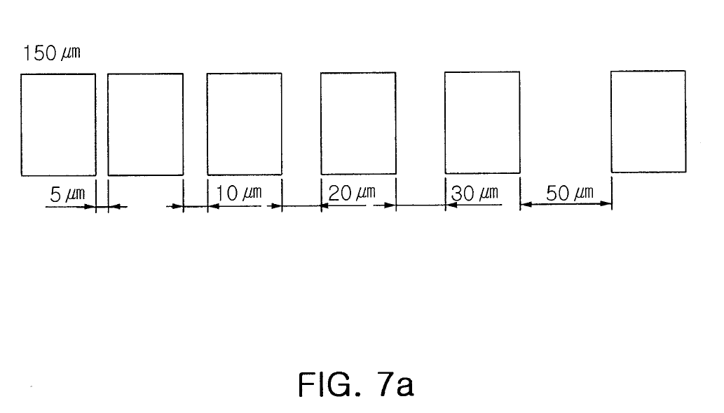

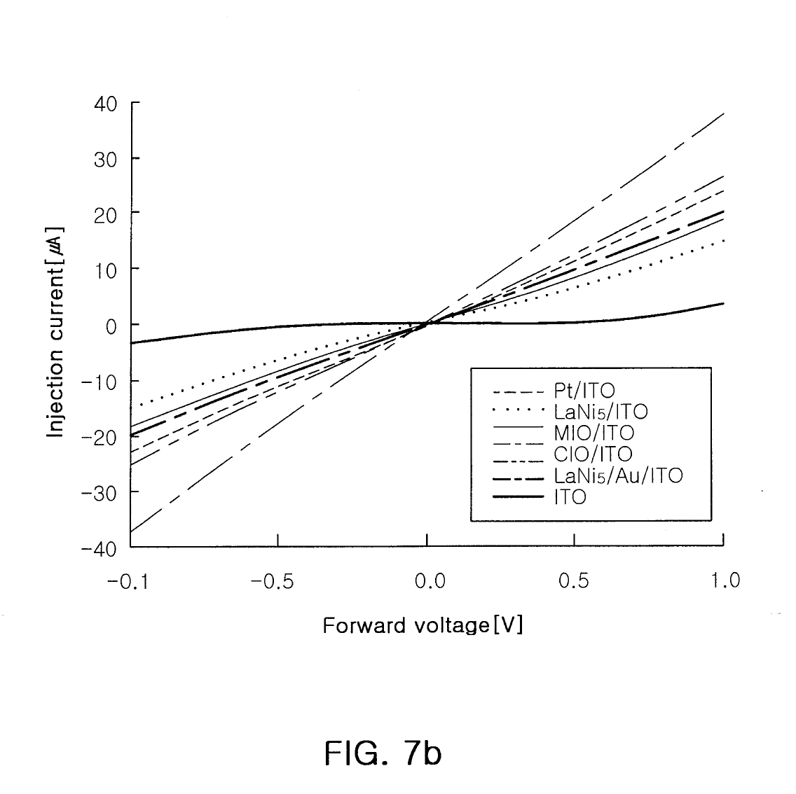

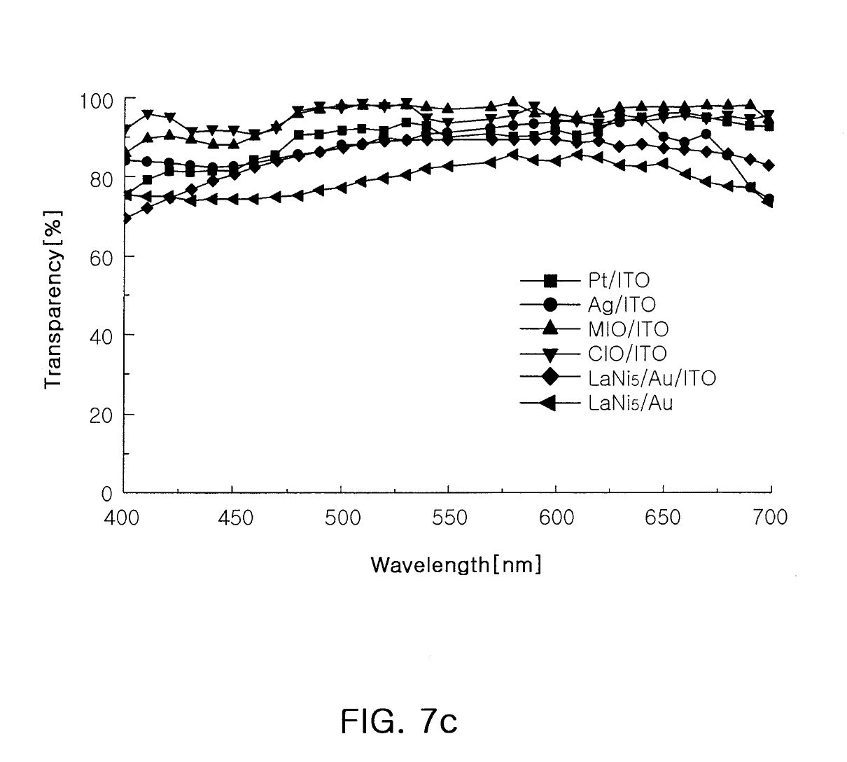

Meanwhile, FIGS. 7a through 7c show comparison results of other experiments on characteristics (transparency and injection current) of the conventional gallium nitride based semiconductor light emitting diode and the gallium nitride based semiconductor light emitting diode in accordance with the present invention. First, FIG. 7a shows TLM (Transmission Length Mode) patterns used in measuring specific contact resistance. Ni/Au and Pt/ITO, and CIO/ITO in accordance with the present invention were patterned on the p-GaN wafer, as shown in FIG. 7a and then resistance between respective pattern spaces was measured. FIGS. 7b and 7c are, respectively, graphs comparing injection current versus forward voltage, and transparency in relation to the respective wavelengths, based on the results as measured.

As can be seen from FIGS. 7b and 7c, the semiconductor light emitting diode having the ohmic contact forming layer in accordance with the present invention has good characteristics in both contact resistance and transparency, as compared to the conventional emitting light diode made of Pt/ITO and Ni/Au.

Table 1 below shows comparison between contact resistance and transparency at an ITO thickness of 460 nm, forward voltage at an injection current of 20 mA, and luminance, respectively, when ITO was present alone, when ITO was vapor deposited on Pt, LaNi5/Au, Ag and LaNi5, respectively, as in conventional arts, and when ITO was formed on CIO as in the present invention, respectively, under the same conditions.

TABLE 1

| | Contact | | Forward | |
|---|---|---|---|---|
| | resistance | | voltage | Luminance |
| | (Ω-cm²) | Transparency (%) | (V) | (mcd) |
| ITO | 5.85 × 10−0 | 100 | 5 | — |
| Pt/ITO | 4.15 × 10−3 | 80 | 3.25 | — |
| LaNi5/Au/ITO | 1.13 × 10−2 | 74 | 3.7 | — |
| Ag/ITO | 3.81 × 10−3 | 93 | 3.3 | 87 |
| CIO/ITO | 4.94 × 10−3 | 96 | 3.35 | 105 |
| LaNi5/Au | 1.39 × 10−3 | 75 | 3.2 | 75 |

As can be seen from Table 1, and described in the present invention, when ITO was formed on the CIO, a contact resistance and transparency nearest to those of pure ITO were obtained without increase of forward voltage. As a result, in the light emitting diode formed in accordance with the present invention, improved luminance characteristics can be exhibited.

In particular, where the ohmic contact forming layer made of CIO is formed, it exhibits higher contact resistance, and transparency characteristics equal to or better than the ohmic contact forming layer made of MIO. In addition, it also shows high transparency characteristics compared to the conventional Pt/ITO and Ag/ITO and thus is applicable for high luminance. Further, when the CIO is used, it shows the lowest forward voltage characteristics during high luminance EPI experiment of patterns.

Next, changes in characteristics were examined for the embodiment in which the reflective layer 29 was formed on the lower surface of the substrate 21.

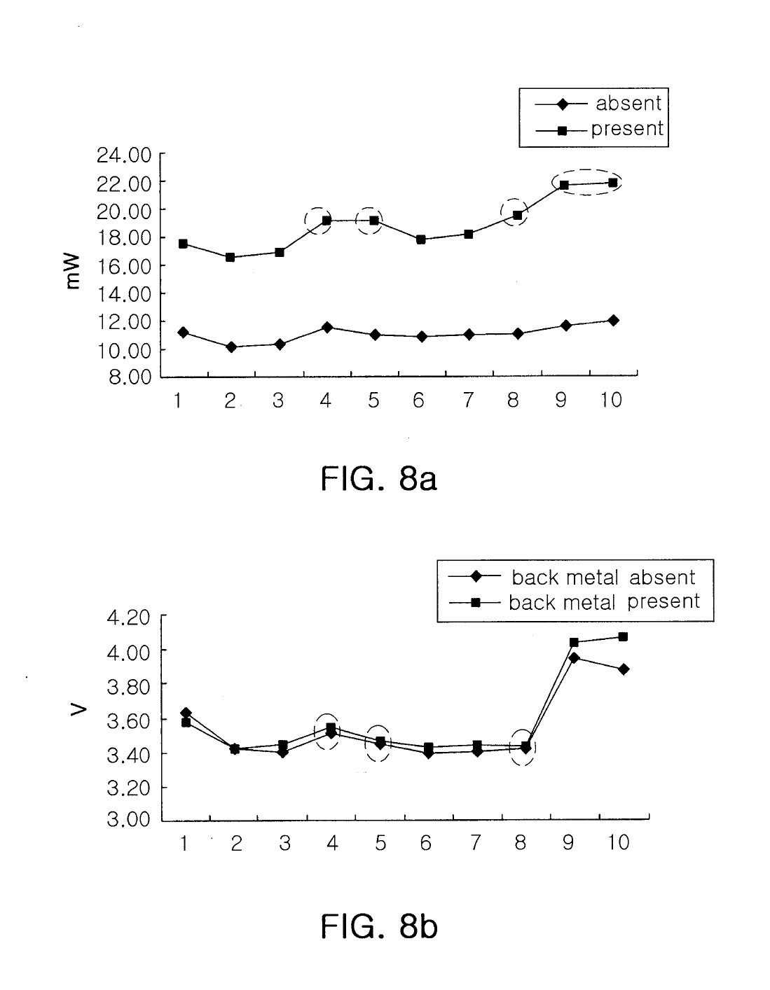

FIG. 8a is a graph comparing progress of changes in optical power (PO) with respect to the presence or absence of the reflective layer 29. FIG. 8b is a graph showing progress of forward voltage, VF1, with respect to the presence or absence of the reflective layer 29. As can be seen from FIGS. 8a and 8b, the optical power can be increased without increase of forward voltage when the reflective layer 29 is additionally formed.

As apparent from the above description, the gallium nitride based semiconductor light emitting diode in accordance with the present invention provides improved transparency characteristics of light while maintaining ohmic characteristics between the upper clad layer and electrode at a predetermined level, and thereby excellent effects capable of improving luminance of the diode.

Further, in the wire bonding type gallium nitride based semiconductor light emitting diode, the present invention provides excellent effects capable of further improving overall luminance characteristics of the light emitting diode by reflecting back light transmitted and scattered through the substrate upward.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1-11. (canceled)

12. A process for preparing a gallium nitride based semiconductor light emitting diode, comprising the step of:
providing a substrate for growing a gallium nitride based semiconductor material;
forming a lower clad layer on the substrate using a first conductive gallium nitride based semiconductor material;
forming an active layer on the lower conductive clad layer using an undoped gallium nitride based semiconductor material;
forming an upper clad layer on the active layer using a second conductive gallium nitride based semiconductor material;
removing at least a portion of the upper clad layer and active layer at a predetermined region so as to expose the corresponding portion of the lower clad layer; and
forming, on the upper surface of the upper clad layer, an ohmic contact forming layer made of In₂O₃ including at least one of Zn, Mg and Cu.

13. The process as set forth in claim 12, wherein the step of forming the ohmic contact forming layer includes forming an alloy layer in a thickness of less than 100 Å on the upper clad layer.

14. The process as set forth in claim 12, wherein the step of forming the ohmic contact forming layer includes vapor-depositing In₂O₃ including one of Mg, Zn and Cu in a predetermined thickness on the upper clad layer followed by heat treatment.

15. The process as set forth in claim 14, wherein the step of forming the ohmic contact forming layer includes heat treating In₂O₃ including one of vapor-deposited Mg, Zn and Cu at a temperature of more than about 200° C. for more than 10 sec.

16. The process as set forth in claim 14, further comprising the step of:
forming a transparent electrode layer on the upper part of the ohmic contact forming layer.

17. The process as set forth in claim 16, wherein the step of forming the transparent electrode layer includes vapor-depositing at least one of ITO (Indium Tin Oxide), ZnO and MgO on the upper part of the ohmic contact forming layer.

18. The process as set forth in claim 16, wherein the step of forming the transparent electrode layer includes vapor-depositing one of ITO (Indium Tin Oxide), ZnO and MgO on the upper part of the ohmic contact forming layer, and heat treating the vapor deposited ITO (Indium Tin Oxide), ZnO or MgO at a temperature of above 200° C. for more than 10 sec.

19. The process as set forth in claim 12, further comprising the step of:
forming, on the upper part of the ohmic contact forming layer, one or more metal layers made of one metal selected from the group consisting of Ag, Pt, Au, Co and Ir.

20. The process as set forth in claim 12, further comprising the step of:
forming, on the lower surface of the substrate, a reflective layer reflecting light emitted toward the substrate upward.

21. The process as set forth in claim 12, further comprising the step of:
forming a reflective layer on the lower and side surfaces of the substrate of the light emitting diode.

22. The process as set forth in claim 20, wherein the step of forming the reflective layer includes alternatively laminating a plurality of high refractivity optical thin films and a plurality of low refractivity optical thin films.

23. The process as set forth in claim 20, wherein the step of forming the reflective layer includes selectively forming an oxide, nitride or metal film, this film being compound of one of Si, Zr, Ta, Ti and Al, and O or N.
